(19) United States
(12) Patent Application Publication
(10) Pub. No.: US 2009/0324816 A1
(43) Pub. Date: Dec. 31, 2009

(54) Low Permeability Gas Recycling in Consolidation

(76) Inventor: Paul Andrew Chludzinski, Hampstead, NC (US)

Correspondence Address: CORNING INCORPORATED, SP-TI-3-1, CORNING, NY, 14831, US

(21) Appl. No.: 12/163,106

(22) Filed: Jun. 27, 2008

(51) Int. Cl. B05D 5/06; C23C 16/44; B01D 53/04

(52) U.S. Cl. 427/163.2; 427/255.28; 95/8; 95/115; 95/90

(57) ABSTRACT

Methods for recycling a low permeability gas such as krypton in the consolidation process of optical fiber manufacturing. The low permeability gas is sent to a purification unit or plant before being reutilized in the consolidation process. The low permeability gas can be used to produce holes or voids in a cladding region of an optical fiber preform. Upon drawing the optical preform into an optical fiber, the voids become elongated in the direction of draw.

### BACKGROUND OF THE INVENTION

1. Field of the Invention

The present invention relates generally to methods and apparatus for recycling gases used in blank consolidation in the production of optical fiber, and particularly to methods and apparatus for recycling low permeability gases used to make voids in optical fiber preforms in the production of microstructured optical fibers.

2. Technical Background

Optical fibers formed of glass materials have been in commercial use for more than two decades. Although such optical fibers have represented a quantum leap forward in the field of telecommunications, work on alternative optical fiber designs continues. One promising type of optical fiber is the microstructured optical fiber, which includes holes, also commonly referred to as voids, running longitudinally along the fiber axis. The holes generally contain air or an inert gas, but may also contain other materials. Microstructured optical fibers may be designed to have a wide variety of properties, and may be used in a wide variety of applications. For example, microstructured optical fibers having a solid glass core and a plurality of holes disposed in the cladding region around the core have been constructed to exhibit relatively low sensitivity to macrobending.

Microstructured optical fibers may be produced in a variety of methods, including methods that include outside vapor deposition (OVD), vapor axial deposition (VAD), inside vapor deposition (IVD), and modified chemical vapor deposition (MCVD). During the production of such fibers, holes or voids may be introduced to a fiber preform by using a low permeability gas atmosphere during consolidation. Low permeability gases are classified as any gases having a molecular weight greater than that of helium. Examples of low permeability gases used for introducing holes or voids to a fiber preform include nitrogen and argon.

When low permeability gases are used to create holes or voids in a fiber preform, the majority of the gas is not physically captured by the consolidating blank and is, instead, allowed to escape into an exhaust stream of a consolidation furnace. The exhaust stream is then typically treated to remove hazardous components (such as halogens and halogen-containing gases) after which the remaining portion of the stream is allowed to vent into the atmosphere. This one time use of low permeability gas can substantially increase production costs, especially where the low permeability gas is relatively expensive.

### SUMMARY OF THE INVENTION

One aspect of the present invention includes a method for recycling a low permeability gas in the consolidation process of optical fiber manufacturing. The method includes feeding a low permeability gas of a first level of purity to a consolidation furnace. Next, the method includes recovering an amount of spent low permeability gas from the consolidation furnace. The method also includes feeding recovered spent low permeability gas to a low permeability gas purifier. In addition, the method includes purifying the recovered spent low permeability gas utilizing the low permeability gas purifier to produce an output stream of recycled low permeability gas satisfactory for reutilization in the consolidation process. The method further includes feeding recycled purified low permeability gas to the consolidation furnace. Additionally, the method includes reutilizing the recycled purified low permeability gas in the consolidation process.

In another aspect, the present invention includes a method of making an optical fiber preform. The method includes forming a soot containing optical fiber preform and consolidating the soot in the soot containing optical fiber preform in a consolidation furnace comprising a low permeability gas under conditions which are effective to trap a portion of the low permeability gas in the preform during the consolidation step, thereby forming a consolidated preform having voids in the preform. Next, the method includes recovering an amount of spent low permeability gas from the consolidation furnace. The method also includes feeding recovered spent low permeability gas to a low permeability gas purifier. In addition, the method includes purifying the recovered spent low permeability gas utilizing the low permeability gas purifier to produce an output stream of recycled low permeability gas satisfactory for reutilization in the consolidation process. The method further includes feeding recycled purified low permeability gas to the consolidation furnace. Additionally, the method includes reutilizing the recycled purified low permeability gas in the consolidation process.

In yet another aspect, the present invention includes a method of making an optical fiber. The method includes forming a soot containing optical fiber preform and consolidating the soot in the soot containing optical fiber preform in a consolidation furnace comprising a low permeability gas under conditions which are effective to trap a portion of the low permeability gas in the preform during the consolidation step, thereby forming a consolidated preform having voids in the preform. Next, the method includes recovering an amount of spent low permeability gas from the consolidation furnace. The method also includes feeding recovered spent low permeability gas to a low permeability gas purifier. In addition, the method includes purifying the recovered spent low permeability gas utilizing the low permeability gas purifier to produce an output stream of recycled low permeability gas satisfactory for reutilization in the consolidation process. The method further includes feeding recycled purified low permeability gas to the consolidation furnace. The method also includes reutilizing the recycled purified low permeability gas in the consolidation process. Additionally, the method includes utilizing the consolidated preform in a manufacturing process to form an optical fiber.

In preferred embodiments, methods disclosed herein additionally include sensing the purity of the recovered spent low permeability gas purified in the purifier to determine whether the recovered spent low permeability gas is satisfactory for reutilization in the consolidation process or not satisfactory for reutilization in the consolidation process. If the recovered spent low permeability gas is not, at this point, satisfactory for reutilization in the consolidation process, methods disclosed herein preferably include determining whether the recovered spent low permeability gas is capable of being further purified for reutilization in the consolidation process. If, at this point, the recovered spent low permeability gas is capable of being further purified for reutilization in the consolidation process, methods disclosed herein preferably include recycling said recovered spent low permeability gas at least one time through said purifier.

In preferred embodiments, the low permeability gas is krypton and at least 90% of the krypton fed to the consolidation furnace is recycled krypton recovered from the consolidation furnace. In particularly preferred embodiments, greater than about 50 percent by volume of a total amount of gas in the consolidation furnace is krypton.

In preferred embodiments, the methods disclosed herein are capable of utilizing a recycled low permeability gas, preferably krypton, during consolidation in order to make an optical fiber preform that comprises a void-containing ring, the ring comprising silica and approximately 1 to 20 area percent voids when the preform is viewed in cross section, wherein the voids are approximately 1 to 10 microns in diameter when the preform is viewed in cross section. Such voids are produced under conditions which are effective to trap a portion of said low permeability gas, preferably krypton, in said preform during consolidation and such conditions preferably comprise a consolidation furnace temperature ranging from 1100° C. to 1550° C. and result in the temperature of the optical fiber preform increasing by at least about 12° C./min.

In additional preferred embodiments, the methods disclosed herein are capable of utilizing a recycled low permeability gas, preferably krypton, during consolidation in order to make an optical fiber that comprises a void-containing ring comprising an average number density of voids greater than 0.5 voids per micron² when the optical fiber is viewed in cross section, wherein the mean void diameter is between 5 and 500 nm, when the optical fiber is viewed in cross section.

In yet additional preferred embodiments, the methods disclosed herein are capable of utilizing a recycled low permeability gas, preferably krypton, during consolidation in order to make an optical fiber that exhibits a bend loss of less than 2 dB per 10 mm diameter turn for an entire fiber length which is greater than 1 m, and the optical fiber has a diameter prior to coating of 125 μm±0.7 μm for an entire fiber length which is greater than 1 m.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description present embodiments of the invention, and are intended to provide an overview or framework for understanding the nature and character of the invention as it is claimed. The accompanying drawings are included to provide a further understanding of the invention, and are incorporated into and constitute a part of this specification. The drawings illustrate various embodiments of the invention, and together with the description serve to explain the principles and operations of the invention.

### BRIEF DESCRIPTION OF THE DRAWINGS

FIG. 1 illustrates an OVD method for forming a soot preform;

FIG. 2 illustrates a schematic diagram of low permeability gas recycling as applied to the consolidation process according to one embodiment of the present invention;

FIG. 3 illustrates a draw process and apparatus that may be employed in the method of the present invention;

FIG. 4 illustrates a SEM photomicrograph of a fiber made in accordance with one embodiment of the invention; and

FIG. 5 schematically illustrates a cross-section of an optical fiber made in accordance with the invention, shown with a coating.

### DETAILED DESCRIPTION OF THE PREFERRED EMBODIMENTS

Reference will now be made in detail to the present preferred embodiments of the invention, examples of which are illustrated in the accompanying drawings. Whenever possible, the same reference numerals will be used throughout the drawings to refer to the same or like parts.

As used herein, “low permeability gas” denotes any gas with a molecular weight greater than that of helium.

As used herein, “non-periodically disposed” or “non-periodic distribution”, denotes that when one takes a cross section (such as a cross section perpendicular to the longitudinal axis) of the optical fiber, the non-periodically disposed holes are randomly or non-periodically distributed across a portion of the fiber. Similar cross sections taken at different points along the length of the fiber will reveal different cross-sectional hole patterns, i.e., various cross sections will have different hole patterns, wherein the distributions of holes and sizes of holes do not match. That is, the voids or holes are non-periodic, i.e., they are not periodically disposed within the fiber structure. These holes are stretched (elongated) along the length (i.e. parallel to the longitudinal axis) of the optical fiber, but do not extend the entire length of the entire fiber for typical lengths of transmission fiber. While not wishing to be bound by theory, it is believed that the holes extend less than a few meters, and in many cases less than 1 meter along the length of the fiber. The terms holes, voids, and seeds are used herein interchangeably.

As used herein, “regional void area percent”, means the total area of the voids in a void containing annular region divided by the total area of the void containing annular region (when the optical fiber is viewed in cross-section taken perpendicular to the axis of the optical fiber) times 100, the void containing region being defined by the inner and outer boundaries of the void containing region. For example, if the radially innermost edge of the radially innermost void in the fiber has a radial location of 10 microns from the axial centerline of the fiber, and the radially outermost edge of the radially outermost void in the fiber has a radial location of 15 microns from the centerline, then the area of the void containing region is approximately 225−100=125 square microns. If the total cross sectional area of voids contained in this void containing region is 5 square microns, then the void area percent of the void containing region is approximately 4 percent.

Methods disclosed herein, in preferred embodiments, can produce optical fiber that is made from a preform that was subjected to preform consolidation conditions in which a significant amount of gases are trapped in a region of the consolidated glass blank, thereby causing the formation of non-periodically distributed voids in the void-containing region of the consolidated glass optical fiber preform. Rather than taking steps to remove these voids, the resultant preform is purposefully used to form an optical fiber with voids therein. In particular, by utilizing relatively low permeability gases and/or relatively high sintering rates, holes can be trapped in the consolidated glass during the consolidation process. The sintering rate can be increased by increasing the sintering temperature and/or increasing the downfeed rate of the soot preform through the sintering zone of the consolidation furnace. Under certain sintering conditions, it is possible to obtain glasses in which the area fraction of the trapped gases is a significant fraction of the total area or volume of the preform.

Such preforms can be used, for example, to make optical fibers having cladding regions which alternate between regions of void free glass and void containing glass. Upon drawing the optical preform into an optical fiber, the voids become elongated in the direction of draw.

Preferred low permeability gases for use in the void forming consolidation step include at least one gas selected from the group consisting of neon, argon, and krypton, and mixtures thereof A particularly preferred void producing low permeability gas is krypton. Applicants have found that when the void producing low permeability gas includes krypton, optical fibers can be produced having an annular void containing glass region with smaller, more numerous, and more uniform voids than when krypton is largely absent as a low permeability gas. Such optical fibers can exhibit improved combinations of properties, such as low bend loss in combination with more precise diameter control during fiber draw. Krypton is, however, relatively expensive as compared to other low permeability gases. Accordingly, embodiments of the present invention can provide for the reclamation of krypton used during consolidation, thereby resulting in substantial krypton and cost savings.

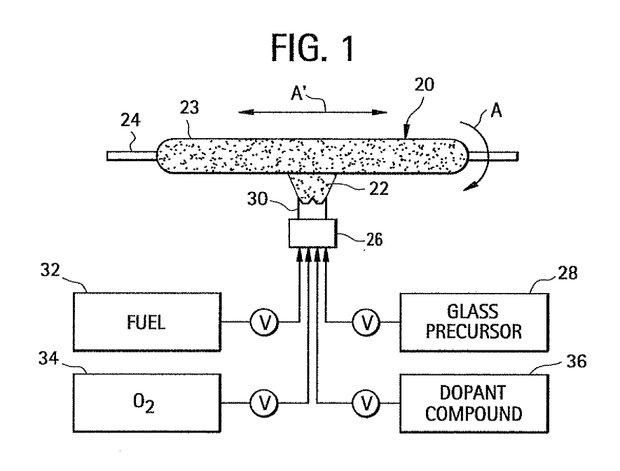

FIG. 1 illustrates a method of manufacturing a soot optical fiber preform 20 that may be used in accordance with methods disclosed herein. In the embodiment illustrated in FIG. 1, soot preform 20 is formed by depositing silica-containing soot 22 onto an outside of a rotating and translating mandrel or bait rod 24. This process is known as the OVD or outside vapor deposition process. Mandrel 24 is preferably tapered. The soot 22 is formed by providing a glass precursor 28 in gaseous form to the flame 30 of a burner 26 to oxidize it. Fuel 32, such as methane (CH₄), and combustion supporting gas 34, such as oxygen, are provided to the burner 26 and ignited to form the flame 30. Mass flow controllers, labeled V, meter the appropriate amounts of suitable dopant compound 36 silica glass precursor 28, fuel 32 and combustion supporting gas 34, all preferably in gaseous form, to the burner 26. The glass former compounds 28, 36 are oxidized in the flame 30 to form the generally cylindrically-shaped soot region 23. In particular, a dopant compound 36 may be included if desired. For example, a germanium compound may be included as an index of refraction increasing dopant (e.g. in the core of the fiber), or a fluorine containing compound may be included to lower the index of refraction (e.g. in the cladding and/or void containing region of the fiber).

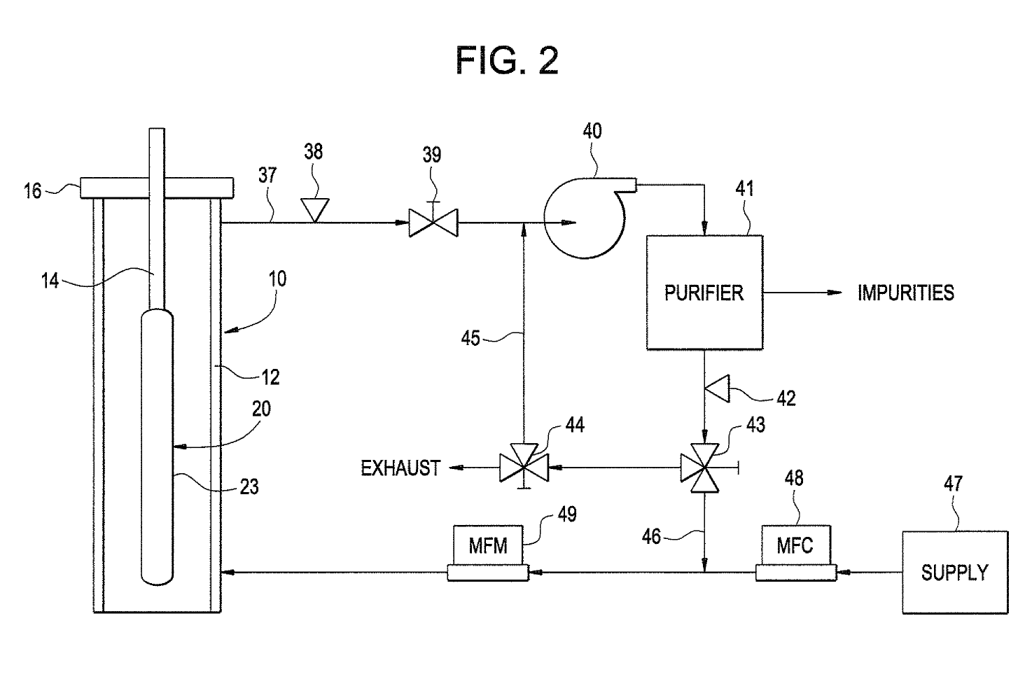

As illustrated in FIG. 2, the soot preform 20 including the cylindrical soot region 23 may be consolidated in a consolidation furnace 10 to form a consolidated blank. Prior to consolidation, the mandrel 24 illustrated in FIG. 1 is removed to form a hollow, cylindrical soot blank preform. During the consolidation process, the soot preform 20 is suspended, for example, inside a pure quartz muffle tube 12 of the furnace 10 by a holding mechanism 14. Preferably, before the consolidation step, the preform 20 is exposed to a drying atmosphere. For example, a suitable drying atmosphere may include about 91 percent to 99 percent helium and 1 percent to 9 percent chlorine gas at a temperature of between about 950° C. and 1250° C. and a suitable drying time ranges from about 0.5 and 4.0 hours. The soot preform can also be doped, if desired, for example using a dopant gas having fluorine or other optical fiber dopants therein. For example, to dope with fluorine, SiF₄ and/or CF₄ gas may be employed. Such dopant gases may be employed using conventional doping temperatures, for example between about 950 and 1250° C. for 0.25 to 4 hours.

During a void trapping consolidation step, which preferably takes place after a soot drying step, the furnace temperature is raised and the preform 20 is consolidated at a suitable temperature, for example between about 1390° C. and 1535° C. to form a consolidated preform. Alternatively, and more preferably, gradient sintering may be employed whereby the soot preform 20 is driven down through a hot zone of the furnace 10 which is maintained at a temperature of between about 1225° C. to 1550° C., more preferably between about 1390° C. and 1535° C. For example, the preform may be held in an isothermal zone which is maintained at a desired drying temperature (950-1250° C.), after which the soot preform is driven through a zone which is maintained at a desired consolidation temperature (e.g. 1225° C. to 1550° C., more preferably 1390° C. and 1535° C.) at a rate of speed which is sufficient to result in the preform 20 temperature increasing by greater than 1° C./min. Upper zones of the furnace can be maintained at lower temperatures which facilitate a drying and impurity removal step. The lower zone can be maintained at the higher temperatures desired for consolidation. Sintering temperatures employed during the void trapping consolidation step preferably range from 1100° C. to 1550° C., more preferably between 1300° C. and 1500° C., and most preferably between 1350° C. and 1500° C. One particularly preferred sintering temperature is approximately 1490° C.

In one preferred embodiment, the soot containing preform is downfed through a consolidation hot zone at a first downfeed rate, followed by downfeeding of the preform through a second hot zone at a second downfeed rate which is less than that of the first downfeed rate. Such a consolidation technique results in the outside portion of the soot preform sintering before the rest of the preform sinters, thereby facilitating trapping of gases which will in turn facilitate formation of and retaining of voids in the resultant consolidated glass. For example, the preform can be exposed to such suitable consolidation temperatures (e.g. greater than about 1390° C.) at a first speed which is sufficient to result in the preform temperature increasing by more than 15° C./min, more preferably greater than 17° C./min, followed by at least a second downfeed rate/consolidation temperature combination which is sufficient to result in the preform heating by at least about 12° C./min, more preferably greater than 14° C./min. Preferably, the first consolidation rate results in the outside of the preform increasing in temperature at a rate which is greater than 2° C./min, more preferably greater than 3° C./min, and most preferably greater than about 4° C./min higher than the heating rate of the second consolidation rate. If desired, a third consolidation step can be employed which heats at a slower rate (e.g. less than 10° C./min). Alternatively, the soot preform can be sintered at even faster rates in order to create more voids by driving the soot preform through a furnace hot zone where the temperature is greater than 1550° C., more preferably greater than 1700° C., even more preferably greater than 1900° C. Alternatively, the soot preform can be sintered at even faster rates external to the furnace by using an open flame or plasma torch in contact with the soot. If desired, the optical fiber preform can be produced using a series of different consolidation steps, some of which may include conventional consolidation steps to completely sinter a particular preform region into a void-free fully consolidated glass, after which additional soot is deposited and sintered using a void trapping consolidation step.

Preferred sintering gases which may be used in the void trapping consolidation step are those which comprise at least one gas selected from the group consisting of neon, argon, and krypton and a particularly preferred void producing low permeability gas is krypton. Each of these gases exhibits a relatively low permeability in silica glass at or below the consolidation temperature which is suitable for forming voids in accordance with the methods present invention.

Preferably these void producing gases are employed either alone or in combination in an amount between 5 and 100 percent by volume, more preferably between about 20 and 100 percent by volume and most preferably between about 40 and 100 percent by volume. The remainder of the sintering gas atmosphere can be made up of a suitable diluent or carrier gas such as, for example, helium, hydrogen, deuterium, or mixtures thereof When the void producing low permeability gas is krypton, it is preferably employed in the consolidation furnace 10 in an amount greater than 10 percent by volume, more preferably greater than 30 percent by volume, even more preferably greater than about 50 percent by volume, and yet even more preferably greater than about 65 percent by volume, with the remainder of the sintering atmosphere being a carrier gas such as, for example, helium. Krypton can also be employed in the consolidation furnace 10 at concentrations greater than 85 percent by volume, including from 85 percent to 100 percent by volume. Voids can also be created by sintering the soot in a low permeability diluent gas under a partial vacuum (e.g., wherein the sintering atmosphere is at a pressure of between about 40 to 750 Torr), and in such cases use of a diluent relatively high permeability gas such as helium is not necessary. Chlorine can be incorporated into the glass by using Cl₂, SiCl₄ or other chlorine containing dopants.

The gaseous atmosphere employed during the consolidation process, the temperature inside the consolidation furnace, and preform consolidation rate are selected so that, during the soot consolidation process, gases are intentionally trapped within the preform, forming holes in the consolidated glass. These gas containing voids are preferably not entirely outgassed prior to and/or during the fiber draw process, so that the voids remain in the fiber after the fiber has been drawn. A variety of process parameters can be controlled to vary and control the size of the voids. For example, increasing the consolidation time or temperature can increase the void size, as the increased temperature causes the gases trapped within the voids to expand. Similarly, the size and area percent of the voids can be impacted by the draw conditions. For example, a longer hot zone in a draw furnace and/or faster draw speeds tend to increase the size as well as the area percent of the holes. Selection of a gas that is more permeable in glass at the consolidation temperature, such as krypton, will result in smaller voids. Sintering rate can also have a significant effect on hole size and hole quantity. A faster sintering rate will result in the formation of more and larger voids. However, use of sintering rates that are too slow will result in no voids being formed, as the gas will have time to escape through the glass. Generally speaking, an optical fiber preform having a lower soot density will result in formation of more voids. The silica containing soot preferably has a bulk density of between about 0.10 g/cc and 1.7 g/cc, more preferably between about 0.30 g/cc and 1.0 g/cc.

Optical preforms produced by methods described herein are preferably comprised of a void-free germania doped core, a void-free silica inner cladding, a void-containing silica ring and a void-free silica overclad. The void-containing ring region can contain over approximately 1,000,000 voids in the cross-sectional slice of the preform wherein the voids can be approximately 1 to 10 microns in average diameter and comprised approximately 1 to 20 area percent voids. These voids are typically discrete and isolated spheroid shape surrounded by silica, therefore each void is non-continuous in the axial or radial position along the length of the optical preform. Upon drawing the optical preform into an optical fiber the voids become elongated in the direction of draw.

In some embodiments, at least some of the voids contain at least one gas selected from the group consisting of neon, argon, and krypton and mixtures thereof More preferably, the voids in the void-containing ring region comprise krypton gas.

Referring again to FIG. 2, low permeability consolidation gas, preferably krypton, is fed from fresh gas supply source 47 through mass flow controller (“MFC”) 48, through mass flow meter (“MFM”) 49, and into consolidation furnace 10. Additional consolidation gases such as oxygen, nitrogen, sulfur hexafluoride, silicon tetrafluoride, chlorine and helium may also be fed to consolidation furnace 10 from respective sources (not shown). During consolidation, some of the low permeability consolidation gas is physically captured by the consolidating blank but the majority of it is not. Accordingly, consolidation furnace preferably includes seal 16 to reduce gas loss to the atmosphere.

Spent gases, including spent low permeability gases, are drawn through recovery line 37, sensor 38, flow control valve 39, and a compressor or pump 40 to a gas purifier 41. Preferably the spent gases contain at least 25% of at least one low permeability gas, such as krypton. Preferably, the amount of spent gas drawn through recovery line 37 is controlled with valve 39 based on at least one measured parameter, such as spent gas composition, spent gas flow, spent gas pressure, spent gas thermal conductivity, spent gas viscosity, and/or spent gas heat capacity. The measurement of the measured parameter is made by a suitable sensor or sensors, such as the sensor 38. If the flow of the spent gas through recovery line 37 is determined to be too high or too low, valve 39 is used to modulate the flow from furnace 10 to pump 40.

For example, if sensor 38 measures spent gas composition, spent gas flow, spent gas pressure, spent gas thermal conductivity, spent gas viscosity, and/or spent gas heat capacity outside of a predetermined range or setpoint, valve 39 can be open or closed by some amount, for example, as determined by a proportional-integral (PI) control loop. MFC 48 can also introduce more or less fresh low permeability gas into the system. Thus, in one embodiment of the system shown in FIG. 1, MFC 48 and valve 39 each act as metering components to regulate the amount of low permeability gas fed into consolidation furnace 10.

In a preferred embodiment, sensor 38 measures spent gas composition, preferably oxygen content. Excessive oxygen in spent gas passing through recovery line 37 is evidence of too much air intrusion into consolidation furnace 10. This can occur from seal 16 being compromised as a result of too much spent gas being recycled back into consolidation furnace 10. Accordingly, by measuring the oxygen content of spent gas through recovery line 37 with sensor 38, valve 39 can be opened or closed to regulate the amount of spent gas being sent to the recycle process. For example, if sensor 38 measures oxygen content above a predetermined range or setpoint, valve 39 can be closed by a certain amount to reduce the amount of spent gas being sent to the recycle process. Conversely, if sensor 38 measures oxygen content below a predetermined range or setpoint, valve 39 can be opened by a certain amount to increase the amount of spent gas being sent to the recycle process. Preferably, the amount of oxygen in spent gas is less than 1%, such as less than 0.3%, and preferably is controlled to range from 0.1% to 1%, even more preferably from 0.1% to 0.3%.

Gas purifier 41 removes contaminants such as chlorine, hydrochloric acid, oxygen, nitrogen, silicon dioxide and any other consolidation process impurities to produce adequately pure low permeability gas for recycling to the consolidation process. Preferably, the low permeable gas is purified to a purity of at least 98%, such as 99%, and even further such as 99.9% upon exit from the gas purifier 41. Preferably, the total amount of the above-listed contaminants is removed to a level of less than 50 ppm by purifier 41. It may be desirable to employ at least a second purifier (not shown) or a series of additional purifiers (not shown) to additionally remove chlorine, hydrochloric acid and fluorine compounds to reduce corrosion problems associated with these components.

In a preferred embodiment, gas purifier 41 can comprise a gas purification plant. The gas purification plant may be located on the same site as consolidation furnace 10 or it may be offsite. In addition, spent low permeability gas may be purified by gas purifier 41 in a continuous or batch mode. Purifying the spent low permeability gas in a batch mode in an offsite gas purification plant may be preferable, for example, if the purification equipment cannot be easily integrated into the optical fiber manufacturing process.

Gas purifier 41 may employ one or more purification arrangements that include various purification components and systems. Exemplary purification components and systems include wet and dry scrubbing systems, solid and fluid separation systems, cryogenic liquid upgrading systems, chemical adsorption systems, catalytic reaction systems, absorption systems, membrane separation systems and pressure or thermal swing adsorption systems. It is contemplated that further advances in such components and systems will be made, and that one of ordinary skill in the art will be able to select and combine such components to match the purification needed for the impurities of a given stream of gas to be recycled. When the low permeability gas to be recycled is krypton, preferred purification components and systems include chemical absorption systems, catalytic reaction systems, and membrane separation systems.

It is preferable to sense the purity of the recycled gas using a sensor 42 in order to determine whether the low permeability gas is satisfactory for reutilization in the consolidation process. In a preferred embodiment, sensor 42 includes at least one of a gas chromatograph (GC) and a mass spectrometer (MS) to measure for the concentration of one or more of a plurality of various contaminants.

As shown in FIG. 2, in a preferred embodiment, gas exiting sensor 42 is drawn through three-way valve 43. Gas measured by sensor 42 as having a sufficient predetermined level of purity to be recycled back to consolidation furnace 10 is drawn through line 46 to be combined with gas fed from fresh supply source 47. Gas measured by sensor 42 as not having a sufficient predetermined level of purity to be recycled back to consolidation furnace 10 is directed to three-way valve 44. If gas arriving at three-way valve 44 has at least a predetermined level of purity (as measured by sensor 42) such that it can be further purified to meet specification, it is drawn through line 45 and combined with spent gas from consolidation furnace 10 to be recycled through purifier 41. If gas arriving at three-way valve 44 does not have at least a predetermined level of purity (as measured by sensor 42) such that it cannot be further purified to meet specification, it is exhausted.

Recycled purified low permeability gas can be optionally fed to a storage tank (not shown) and then optionally fed through a MFC (not shown) to join gas fed from fresh gas supply source 47 in order to be fed to the consolidation furnace 10 and reutilized in the consolidation process. Total flow to the consolidation furnace 10, can be measured by MFM 49 and the flow through MFC 48 can be adjusted such that the MFM 49 measurement is maintained within a pre-determined range or at a pre-determined setpoint.

In practice, at least MFC 48 and flow control valve 39 are controlled, preferably simultaneously, to adjust the mix of recycled purified low permeability gas and low permeability gas from fresh gas supply source 47 to reflect low permeability gas losses and recycling inefficiencies. Scrubbers (not shown) can be provided to process any vented gases. In addition, as illustrated by the above preferred embodiments, controlling the amount of gas passing through valves 39, 43 and 44, and MFC 48, can allow for control of the amount of gas extracted from consolidation furnace 10 (in view of seal 16 design), the purity of the recycled product delivered through line 46, and the total flow of low permeability gas fed to consolidation furnace 10.

The low permeability gas fed to the consolidation furnace 10 (i.e., the gas fed from the fresh gas supply source 47 in combination with the recycled purified low permeability gas from line 46) preferably has a level of purity of at least 99.9%, such as at least 99.95%. In a particularly preferred embodiment, the low permeability gas is krypton.

Preferably, at least 90% of the low permeability gas fed to the consolidation furnace 10 is recycled purified low permeability gas recovered from the consolidation furnace 10. Even more preferably, at least 95% of the low permeability gas fed to the consolidation furnace 10 is recycled purified low permeability gas recovered form the consolidation furnace 10. In a particularly preferred embodiment, the low permeability gas is krypton.

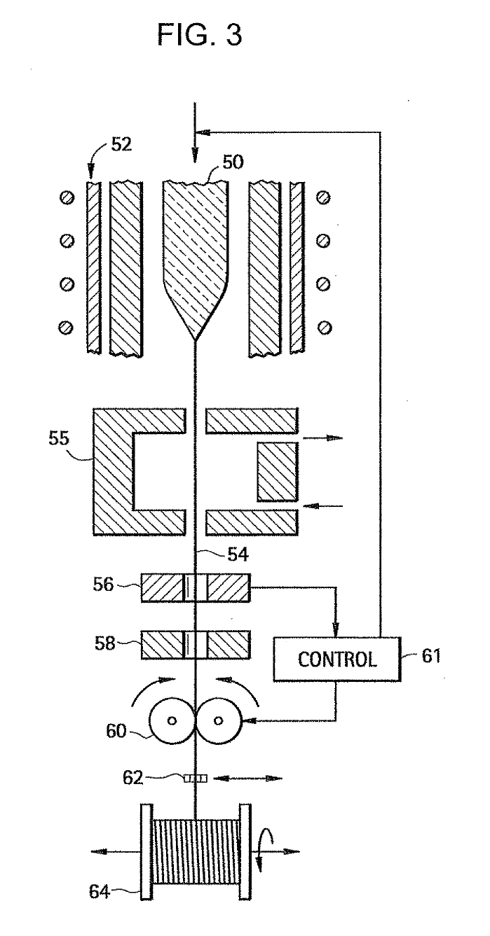

In any of the embodiments disclosed herein, the resulting final consolidated optical fiber preform 50 may be drawn into an optical fiber by positioning the preform within a draw furnace 52 as shown in FIG. 3, and then heating and drawing the optical fiber 54 using conventional methods and apparatus. The fiber 54 is then cooled in cooling chamber 55 and measured for final diameter by non-contact sensor 56. One or more coatings may be applied and cured by coating apparatus 58. During draw, the fiber 54 passes through a tension assembly 60 whereby tension is applied to draw the fiber 54 from the preform 50. The tension is controlled via control apparatus 61 to maintain the fiber diameter at a predetermined set point. Finally, the coated fiber 54 is wound by feedhead 62 onto a fiber storage spool 64.

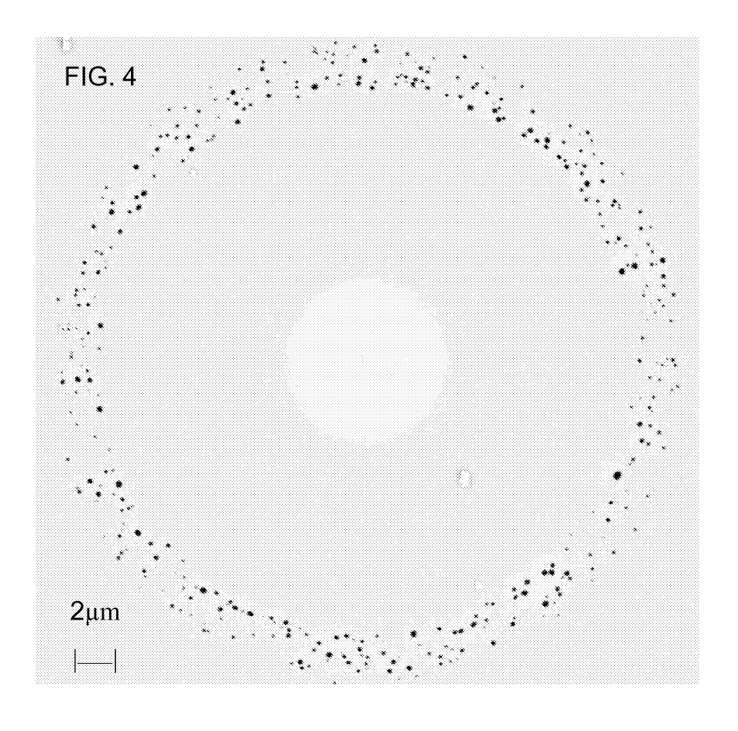

Using the void producing consolidation techniques disclosed herein, it is possible to make optical fibers whose cladding comprises a void containing region having a regional void area percent greater than 0.5 percent, more preferably greater than about 1 percent, even more preferably greater than about 5 percent and even more preferably greater than about 10 percent. Most preferably, the region having holes does not extend to the outer edge of the cladding such that there are open voids or holes on the outside of the fiber. An example of such a fiber is illustrated in FIG. 4. The fiber in FIG. 4 comprises a core region which is surrounded by a cladding region which comprises voids which are positioned to be effective to guide light along the silica core. The voids in the fiber illustrated in FIG. 4 were produced by using krypton as the void producing low permeability gas during consolidation.

Using the void producing consolidation techniques described herein, optical fibers can be made wherein the maximum size of any of the voids, in the region where the fraction of power of light is greater than 80 percent, is less than the wavelength of light being transmitted, the maximum size of any of the voids being the maximum diameter of any particular void when the optical fiber is viewed in perpendicular cross-section transverse to the longitudinal axis of the fiber. For example, in preferred embodiments, the mean void diameter in the void containing region is between 5 and 500 nm, more preferably between 30 and 300 nm, even more preferably between 30 and 200 nm, and most preferably between 30 and 150 nm.

Using the void producing consolidation techniques described herein, optical fibers can be made that exhibit a non-periodic void containing region, which when viewed in cross-section, exhibits greater than 100 voids, more preferably greater than 200 voids, even more preferably greater than 400 voids, and in some embodiments greater than 600 voids in the annular void containing region of a given optical fiber perpendicular cross-section.

Using the void producing consolidation techniques described herein, optical fibers can be made that exhibit a non-periodic void containing region, which when viewed in cross-section, exhibits an average number density of holes greater than 0.5 holes per micron², more preferably greater than 1.0 holes per micron², even more preferably greater than 2 holes per micron², and yet even more preferably greater than 5 holes per micron².

The hole number, mean diameter, max diameter, and total void area percent of holes can all be calculated with the help of a scanning electron microscope at a magnification of about 7500× and image analysis software, such as ImagePro, which is available from Media Cybernetics, Inc. of Silver Spring, Md., USA.

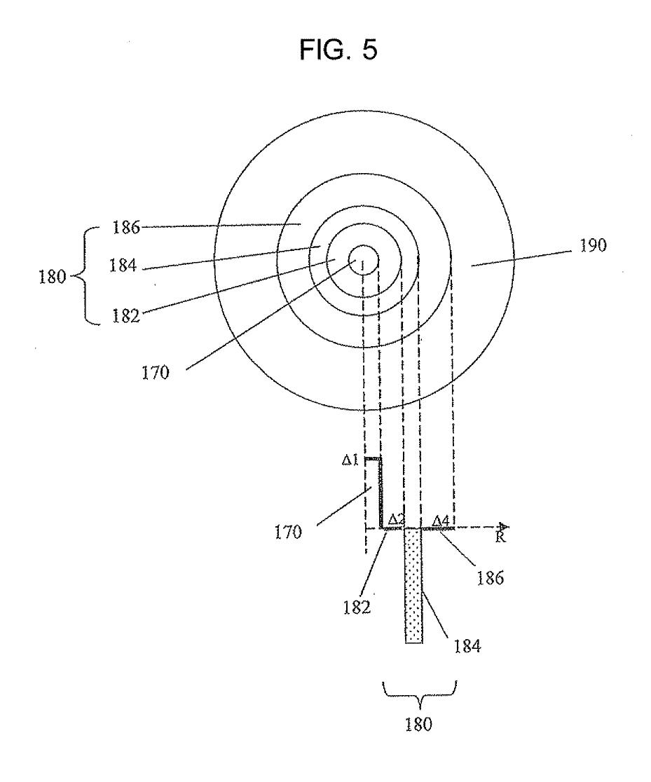

In one set of preferred embodiments, the core region includes doped silica to provide a positive refractive index relative to pure silica, e.g. germania doped silica. The core region is preferably hole-free. As illustrated in FIG. 5 in some embodiments, the core region 170 comprises a single core segment having a positive maximum refractive index relative to pure silica Δ₁ in %, and the single core segment extends from the centerline to a radius R₁. In one set of embodiments, 0.30%<Δ₁<0.40%, and 3.0 ηm<R₁<5.0 μm. In some embodiments, the single core segment has a refractive index profile with an alpha shape, where alpha is 6 or more, and in some embodiments, alpha is 8 or more. In some embodiments, the inner annular hole-free region 182 extends from the core region to a radius R₂, wherein the inner annular hole-free region has a radial width equal to R₂−R₁, which is greater than 1 μm. Radius R₂ is preferably greater than 8 μm, more preferably greater than 10 μm. The ratio of the core radius R₁ to R₂, R₁/R₂, is preferably between 0.2 and 0.6, more preferably between 0.3 and 0.5 and even more preferably between 0.33 and 0.45. The intermediate annular hole-containing region 184 extends radially outward from R₂ to radius R₃ and has a radial width equal to R₃−R₂. The outer annular region 186 extends radially outward from R₃ to radius R₄. Radius R₄ is the outermost radius of the silica portion of the optical fiber. One or more coatings 190 may be applied to the external surface of the silica portion of the optical fiber, starting at R₄, the outermost diameter or outermost periphery of the glass part of the fiber. The core region 170 and the cladding region 180 are preferably comprised of silica. The core region 170 is preferably silica doped with one or more dopants. Preferably, the core region 170 is hole-free. The hole-containing region 184 has an inner radius R₂ which is preferably not more than 20 μm. In some embodiments, R₂ is not less than 10 μm and not greater than 20 μm. In other embodiments, R₂ is not less than 10 μm and not greater than 18 μm. In other embodiments, R₂ is not less than 10 μm and not greater than 14 μm. The hole-containing region 184 has a radial width which is preferably not less than 0.5 μm. In some embodiments, hole-containing region 184 has a radial width that is not less than 0.5 μm and not greater than 20 μm. In other embodiments, hole-containing region 184 has a radial width that is not less than 2 μm and not greater than 12 μm. In other embodiments, hole-containing region 184 has a radial width that is not less than 2 μm and not greater than 8 μm.

The cladding region 180 extends to a radius R₄ which is preferably not less than 40 μm. In some embodiments, R₄ is about 40 μm. In other embodiments, R₄ is not less than 60 μm. In other embodiments, R₄ is about 62.5 μm. In some embodiments, the outer annular region 186 has a radial width not less than 20 μm. In other embodiments, the outer hole-free region 186 has a radial width not less than 30 μm. In still other embodiments, the outer hole-free region 186 has a radial width not less than 40 μm. In some embodiments, the core region 170 comprises germania doped silica. In other embodiments, the core region 170 comprises fluorine doped silica.

Preferably, a coating 190 surrounds and is directly adjacent the cladding region. In some embodiments, the optical fiber comprises a single coating layer surrounding and directly adjacent the cladding region.

In some embodiments, at least some of the holes in hole-containing region 184 contain at least one gas selected from the group consisting of neon, argon, and krypton and mixtures thereof. More preferably, the holes in hole-containing region 184 comprise krypton gas.

Using the void producing consolidation techniques disclosed herein, it is possible to achieve hole distribution uniformities throughout the circumference and width of hole-containing region 184 and along the length of the fiber to result in a maximum bend loss less than 2 dB per 10 mm diameter turn, more preferably less than 1 dB per 10 mm diameter turn, and most preferably less than 0.5 dB per 10 mm diameter turn, for an entire fiber length which is greater than 1 m, more preferably greater than 2 m, and even more preferably greater than 100 m, and yet even more preferably greater than 10 km.

In addition, by using krypton as the void producing low permeability gas during consolidation, it is possible to produce optical fiber having more uniform diameter while still possessing the above bend loss characteristics. For example, it is possible to produce optical fiber having a variation in diameter that is less than about 1% of the total fiber diameter which diameter is measured prior to the fiber being coated (such as is shown, for example, in FIG. 3, wherein cooled fiber 54 is measured for final diameter by non-contact sensor 56), such as less than about 0.5% of the total fiber diameter, for an entire fiber length which is greater than 1 m, more preferably greater than 10 m, and even more preferably greater than 100 m, and yet even more preferably greater than 10 km. For example, it is possible to produce an optical fiber having a diameter of 125 μm±0.7 μm, such as 125 μm±0.4 μm for an entire fiber length which is greater than 1 m, more preferably greater than 10 m, and even more preferably greater than 100 m, and yet even more preferably greater than 10 km.

It will be apparent to those skilled in the art that various modifications and variations can be made to the present invention without departing from the spirit and scope of the invention. Thus it is intended that the present invention cover the modifications and variations of this invention provided they come within the scope of the appended claims and their equivalents.

What is claimed is:

1. A method for recycling a low permeability gas in the consolidation process of optical fiber manufacturing, the method comprising:
feeding a low permeability gas of a first level of purity to a consolidation furnace;
recovering an amount of spent low permeability gas from the consolidation furnace;
feeding recovered spent low permeability gas to a low permeability gas purifier;
purifying the recovered spent low permeability gas utilizing the low permeability gas purifier to produce an output stream of recycled low permeability gas satisfactory for reutilization in the consolidation process;
feeding recycled purified low permeability gas to the consolidation furnace; and
reutilizing the recycled purified low permeability gas in the consolidation process.

2. The method of claim 1, wherein the low permeability gas is selected from the group consisting of neon, argon, and krypton.

3. The method of claim 1, wherein the low permeability gas is krypton.

4. The method of claim 1, further comprising sensing the amount of spent low permeability gas recovered from the consolidation furnace based upon at least one measured parameter selected from the group consisting of spent gas composition, spent gas flow, spent gas pressure, spent gas thermal conductivity, spent gas viscosity, and spent gas heat capacity.

5. The method of claim 1, wherein at least 90% of the low permeability gas fed to the consolidation furnace is recycled purified low permeability gas recovered from the consolidation furnace.

6. The method of claim 1, further comprising sensing the purity of the recovered spent low permeability gas purified in the purifier to determine if the recovered spent low permeability gas is satisfactory for reutilization in the consolidation process or not satisfactory for reutilization in the consolidation process, and if not satisfactory for reutilization in the consolidation process, determining whether the recovered spent low permeability gas is capable of being further purified for reutilization in the consolidation process, and if capable of being further purified for reutilization in the consolidation process, recycling said recovered spent low permeability gas at least one time through said purifier.

7. The method of claim 3, wherein greater than about 50 percent by volume of a total amount of gas in the consolidation furnace is krypton.

8. A method of making an optical fiber preform, the method comprising:
forming a soot containing optical fiber preform;
consolidating the soot in said soot containing optical fiber preform in a consolidation furnace comprising a low permeability gas under conditions which are effective to trap a portion of said low permeability gas in said preform during said consolidation step, thereby forming a consolidated preform having voids in said preform;
recovering an amount of spent low permeability gas from the consolidation furnace;
feeding recovered spent low permeability gas to a low permeability gas purifier;
purifying the recovered spent low permeability gas utilizing the low permeability gas purifier to produce an output stream of recycled low permeability gas satisfactory for reutilization in the consolidation process;
feeding recycled purified low permeability gas to the consolidation furnace; and
reutilizing the recycled purified low permeability gas in the consolidation process.

9. The method of claim 8, wherein the low permeability gas is selected from the group consisting of neon, argon, and krypton.

10. The method of claim 8, wherein the low permeability gas is krypton.

11. The method of claim 8, wherein at least 90% of the low permeability gas fed to the consolidation furnace is recycled purified low permeability gas recovered from the consolidation furnace.

12. The method of claim 8, wherein the conditions which are effective to trap a portion of said low permeability gas in said preform during said consolidation step comprise a consolidation furnace temperature ranging from 1100° C. to 1550° C. and result in the temperature of the optical fiber preform increasing by at least about 12° C./min.

13. The method of claim 8, wherein the preform comprises a void-containing ring comprising silica and approximately 1 to 20 area percent voids when the preform is viewed in cross section, wherein the voids are approximately 1 to 10 microns in diameter when the preform is viewed in cross section.

14. A method of making an optical fiber, the method comprising:
forming a soot containing optical fiber preform;
consolidating the soot in said soot containing optical fiber preform in a consolidation furnace comprising a low permeability gas under conditions which are effective to trap a portion of said low permeability gas in said preform during said consolidation step, thereby forming a consolidated preform having voids in said preform;
recovering an amount of spent low permeability gas from the consolidation furnace;
feeding recovered spent low permeability gas to a low permeability gas purifier;
purifying the recovered spent low permeability gas utilizing the low permeability gas purifier to produce an output stream of recycled low permeability gas satisfactory for reutilization in the consolidation process;
feeding recycled purified low permeability gas to the consolidation furnace;
reutilizing the recycled purified low permeability gas in the consolidation process; and
utilizing said consolidated preform in a manufacturing process to form an optical fiber.

15. The method of claim 14, wherein the low permeability gas is selected from the group consisting of neon, argon, and krypton.

16. The method of claim 14, wherein the low permeability gas is krypton.

17. The method of claim 14, wherein at least 90% of the low permeability gas fed to the consolidation furnace is recycled purified low permeability gas recovered from the consolidation furnace.

18. The method of claim 14, wherein the conditions which are effective to trap a portion of said low permeability gas in said preform during said consolidation step comprise a consolidation furnace temperature ranging from 1100° C. to 1550° C. and result in the temperature of the optical fiber preform increasing by at least about 12° C./min.

19. The method of claim 14, wherein the optical fiber comprises a void-containing ring comprising an average number density of voids greater than 0.5 voids per micron² when the optical fiber is viewed in cross section, wherein the mean void diameter is between 5 and 500 nm, when the optical fiber is viewed in cross section.

20. The method of claim 14, wherein the optical fiber exhibits a bend loss of less than 2 dB per 10 mm diameter turn for an entire fiber length which is greater than 1 m, and the optical fiber has a diameter prior to coating of 125 μm±0.7 μm for an entire fiber length which is greater than 1 m.
